(19) United States
(12) Patent Application Publication
(10) Pub. No.: US 2023/0134638 A1
(43) Pub. Date: May 4, 2023

(54) METHOD AND SYSTEMS FOR VIBRATION-BASED STATUS MONITORING OF ELECTRIC ROTARY MACHINES

(71) Applicant: Siemens Aktiengesellschaft, 80333 München (DE)

(72) Inventors: Martin Brückel, Erlangen (DE); Pranita Rajan PRADHAN, Erlangen (DE)

(73) Assignee: Siemens Aktiengesellschaft, 80333 München (DE)

(21) Appl. No.: 17/979,500

(22) Filed: Nov. 2, 2022

(30) Foreign Application Priority Data
Nov. 3, 2021 (EP) 21206218.6

(51) Int. Cl. G01H 1/00

(52) U.S. Cl. CPC G01H 1/003

(57) ABSTRACT

A computer-implemented method for training a model for recommending threshold values of at least one spatial vibration component of an electric rotary machine. A computer-implemented method for monitoring a status of an electric rotary machine using the trained model. A computer program product with commands for carrying out the methods, a machine-readable storage medium with a computer program product, and a data transmission signal which carries the commands. A sensor and computing facility for monitoring a status of an electric rotary machine which is designed to detect data relating to the operation of the electric rotary machine on the electric rotary machine. The sensor and computing facility has commands which, when executed by the sensor and computing facility, cause the sensor and computing facility to carry out the training method and/or the status monitoring method.

### CROSS-REFERENCES TO RELATED APPLICATIONS

This application claims the priority of European Patent Application, Serial No. 21206218.6, filed Nov. 3, 2021, pursuant to 35 U.S.C. 119(a)-(d), the disclosure of which is incorporated herein by reference in its entirety as if fully set forth herein.

### BACKGROUND OF THE INVENTION

The invention relates to a method and systems for vibration-based status monitoring of electric rotary machines. The invention further relates to a computer-implemented method for training a model for recommending threshold values of at least one spatial vibration component of an electric rotary machine, to a computer-implemented method for monitoring a status of an electric rotary machine, and to a computer program product with commands for carrying out the aforementioned methods, a machine-readable storage medium with such a computer program product and a data transmission signal which carries the aforementioned commands. In addition, the invention relates to a sensor and computing facility for monitoring a status of an electric rotary machine.

The following discussion of related art is provided to assist the reader in understanding the advantages of the invention, and is not to be construed as an admission that this related art is prior art to this invention.

In the status monitoring of electric drives, for example, of electric motors, in particular, of low-voltage motors, and their industrial applications, one of the most important measured variables is vibration as, provided it is measured using sufficiently good measurement technology and in sufficient proximity to the mechanical components, this is a good indicator of possible faults and damage cases. Many devices for semi-/automatic status monitoring therefore evaluate the vibration data and the vibration level in general to make statements about the “state of health” of the drive. A fundamental problem here is that vibration measurement may depend on many external factors, particularly if it is not measured directly on the mechanical components (for example, bearing housings). In particular, the load state of the motor in a predetermined application has a major influence on the vibration amplitude, as well as the rotational speed. The common solutions only use the vibration measurement for analysis and attempt to distinguish different cluster / vibration points on the basis of the vibration measurement, frequently without knowing the exact operating point.

However, in order to be able to detect even very small changes in the vibration amplitude over a longer period of time and over different load states (rotational speed and/or torque are varied) of the application, it is essential to be able to distinguish the different load states as accurately as possible and thus to assign the individual vibration measurements to these in order then to compare the vibration measurements over a longer period of time, for example over several months, for the same operating points and to check them for deviations.

An application is known which processes motor data detected by means of a sensor, calculates and displays torque, rotational speed and three-dimensional vibration values. With this application, a threshold value check can be carried out, a user being able to adapt this threshold value. When calculating the threshold value recommendation and checking for exceedance, the application does not take into account the operating point, so that minor changes, above all at individual operating points, cannot be detected. This leads to an unsatisfactory threshold value check and thus to poor status monitoring.

It would therefore be desirable and advantageous to address this problem and to obviate other prior art shortcomings by improving vibration-based status monitoring of electric rotary machines.

### SUMMARY OF THE INVENTION

According to one aspect of the invention, a computer-implemented method for training a model for recommending threshold values of at least one spatial vibration component of an electric rotary machine includes providing historical data which comprise time series of at least two operating parameters and at least one spatial vibration component of the electric rotary machine, detecting operating plateaus in the historical data, with each operating plateau being defined when the at least two operating parameters are constant over a predeterminable period of time (e.g. between 10 and 30 min), performing a cluster analysis on the detected operating plateaus in order to detect operating point clusters, with the various operating point clusters defining various operating states of the electric rotary machine, determining threshold values to be recommended for the defined operating states for the at least one spatial vibration component (different recommendations for different operating states), and providing the defined operating states and the threshold values to be recommended for the defined operating states.

According to another advantageous feature of the invention, a center of gravity can be estimated for each operating point cluster. For example, the center of gravity can be estimated by calculating a cluster mean value.

According to another advantageous feature of the invention, a threshold value to be recommended can be calculated for each operating state.

According to another advantageous feature of the invention, the historical data can include time series of two or three spatial vibration components, and threshold values to be recommended can be determined for the two or three spatial vibration components being determined for the defined operating states. For example, a Bayesian Gaussian Mixture Model (BGMM) can be applied to the time series of the spatial vibration component.

According to another advantageous feature of the invention, different identification can be assigned to different operating point clusters (for example, figure, number, color, etc.).

According to another advantageous feature of the invention, different identification can be assigned to different operating plateaus (figure, number, color, etc.)

According to another advantageous feature of the invention, two operating plateaus can be different (for example, then and only then) when at least one of the at least two operating parameters is different.

According to another advantageous feature of the invention, the operating parameters can be rotational speed and slip frequency.

According to another advantageous feature of the invention, the time series of the historical data can go back up to one month.

Further parameters relating to the operation of the electric rotary machine are: temperature, electrical stator frequency, torque, electrical power and electrical energy, as well as effective values of the spatial vibration components.

According to another aspect of the invention, a computer-implemented method for monitoring a status of an electric rotary machine includes providing actual data which comprise time series of at least two operating parameters and at least one spatial vibration component of the electric rotary machine, detecting operating plateaus in the actual data, with each operating plateau being defined when the at least two operating parameters are constant over a predeterminable period of time, for example, between 10 and 30 minutes, in particular 15 minutes, providing a model trained as described above, assigning the detected operating plateaus to the operating states defined by the trained model in order to be able to map the time series of the at least one spatial vibration component (corresponding to the detected operating plateaus) to the operating states defined by the trained model, checking whether values of the at least one spatial vibration component exceed a threshold value recommended by the trained model, and when the values of the at least one spatial vibration component exceed the threshold value, outputting a warning message according to a predeterminable criterion.

According to another advantageous feature of the invention, each plateau can be assigned in each case to a status, for example, by calculating a Euclidean distance between the data point and the center of gravity of the status.

According to another advantageous feature of the invention, the warning message can be output when at least three successive values of the at least one spatial vibration component exceed the threshold value.

According to another advantageous feature of the invention, the actual data can include time series of two or three spatial vibration components, and it is checked whether values of the two or three spatial vibration components exceed corresponding threshold values recommended by the trained model.

According to another advantageous feature of the invention, an effective value for each spatial vibration component can be calculated for each value of the at least one spatial vibration component which exceeds the threshold value, a geometric mean can be calculated from the calculated effective values, and the warning message can be output if the geometric mean exceeds a predetermined value, for example, 4 mm/s.

According to another advantageous feature of the invention, the warning message can include a number of exceedances and associated time stamps.

According to another advantageous feature of the invention, the time series of the actual data can go back up to two days.

According to another advantageous feature of the invention, the actual data can be stored and at predetermined time intervals, for example, every month, the model can be retrained according to a training method described above.

According to still another aspect of the invention, a sensor and computing facility for monitoring a status of an electric rotary machine is designed to detect data which relates to an operation of the electric rotary machine on the electric rotary machine and which comprises time series of at least two operating parameters and of at least one spatial vibration component of the electric rotary machine, wherein the sensor and computing facility includes commands, which, when executed by the sensor and computing facility, cause the sensor and computing facility to carry out a training method as described above and/or a status monitoring method described above.

According to another advantageous feature of the invention, the electric rotary machine can be designed as an electric motor, in particular, as a low-voltage motor.

According to another advantageous feature of the invention, the electric rotary machine can be under a temporally variable load during operation, wherein the temporally variable load is advantageously characterized by temporally varying torque or temporally varying rotational speed.

According to another advantageous feature of the invention, the sensor and computing facility can be set up to visualize calculated data (vibration values, torque, rotational speed).

The invention is based on a recognition that threshold-value-based status monitoring can be improved when a distinction is made between the different operating points and their own vibration threshold values are determined for each of the operating points found.

The determined vibration threshold values can be as close as possible to the expected value of the vibration amplitude and cap the effective values (RMS values for Root Mean Square) of the vibration measurement. In electrical engineering, the effective value is understood to mean the quadratic mean of a physical variable which varies over time. At the same time, however, the limit values should not be selected to be too small in order to reduce the number of false alarms and to react only if “relevant” threshold values are exceeded.

As described above, this can be achieved by filtering both in the range of values by clustering according to the physical parameters according to frequent operating points, as well as simultaneously in the time range by the plateau detection method. As a result, it is possible to indicate specific threshold values for the vibration for the most frequent and at the same time temporally constant operating points, so that even small jumps or changes in the vibration level over a mean time period (< 1 month) can already be detected, external influences in the form of short-term oscillations of the vibration level being filtered out at the same time, and finally it being possible to ensure the criticality by comparison with a standard.

Advantages emerge in better recognition of fault conditions in the electric rotary machine and thus also in the application since external dependencies and/or disturbance variables can be better filtered out. At the same time, the number of fault messages can be reduced as a message can only be generated when there is clearly recognizable criticality, but at the same time, even in the case of long-term operation with vibrations above the standard values, smaller changes over time can be detected and reported.

As a result, it is possible to detect deteriorations in the “state of health” even in drives with greater damage or high-vibration operating points, so that a more comprehensive inspection can be initiated in situ, or the data can be examined manually.

### BRIEF DESCRIPTION OF THE DRAWINGS

Other features and advantages of the present invention will be more readily apparent upon reading the following description of currently preferred exemplified embodiments of the invention with reference to the accompanying drawings, in which:

FIG. 1 is a flow chart of a computer-implemented training method according to the invention;

FIG. 2 is a graphical illustration of a result of a plateau detection;

FIG. 3 is a graphical illustration of a result of a cluster analysis;

FIG. 4 is a graphical illustration of different threshold value recommendations for different operating states;

FIG. 5 is a block diagram of a system for performing the training method of FIG. 1;

FIG. 6 is a flow chart of a computer-implemented status monitoring method according to the invention;

FIG. 7 is a graphical illustration of a result of an assignment of the actual operating plateaus to the operating states from the trained model; and

FIG. 8 is a schematic illustration of a sensor and computing facility for monitoring a status of an electric rotary machine.

### DETAILED DESCRIPTION OF PREFERRED EMBODIMENTS

Throughout all the figures, same or corresponding elements may generally be indicated by same reference numerals. These depicted embodiments are to be understood as illustrative of the invention and not as limiting in any way. It should also be understood that the figures are not necessarily to scale and that the embodiments may be illustrated by graphic symbols, phantom lines, diagrammatic representations and fragmentary views. In certain instances, details which are not necessary for an understanding of the present invention or which render other details difficult to perceive may have been omitted.

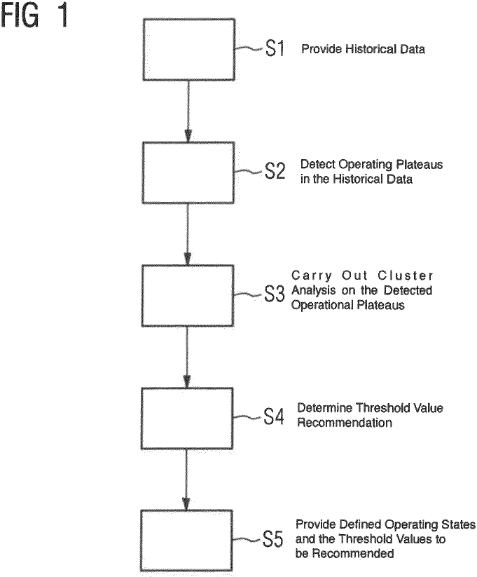

Turning now to the drawings, and in particular to FIG. 1, there is show a flow chart of a computer-implemented method corresponding to a method according to the invention. In the method, a model is trained which recommends threshold values of at least one spatial vibration component of an electric rotary machine.

In a step S1 of the training method, historical data is provided. The historical data comprises time series of at least two operating parameters and at least one spatial vibration component of the electric rotary machine. The electric rotary machine can be, for example, an electric motor, in particular, a low-voltage motor.

The operating parameters are preferably rotational speed and slip frequency.

The time series of the historical data go back, for example, up to one month and thus offer a good overview of the behavior of the electric rotary machine in the most recent past. The period of one month is by no means to be understood as a limitation here - on the one hand, older data can also be used if it is available, on the other hand, shorter time intervals are also possible if it makes sense to retrain the model more often (see below).

Further parameters relating to the operation of the electric rotary machine may include temperature, electrical stator frequency, torque, electrical power and electrical energy, effective values of the spatial vibration components, etc.

All operating parameters can be combined into groups. Operating parameters such as temperature and electrical stator frequency are often referred to as high-frequency KPIs (Key Performance Indicator) because they are measured approximately once a minute during operation of the machine. Other operating parameters such as, for example, torque, electrical power and electrical energy are referred to as low-frequency KPIs. They are recorded less frequently - approximately every three minutes.

In a further step S2, operating plateaus are detected in the historical data. An operating plateau is defined in that the at least two operating parameters are/remain constant over a predeterminable period of time, for example, between 10 and 30 minutes, in particular, 15 minutes. The values 10, 15, 30 minutes serve as guide values and are, generally speaking, dependent on the type of motor. For example, it can take up to 30 minutes for a motor to reach its intended operating state.

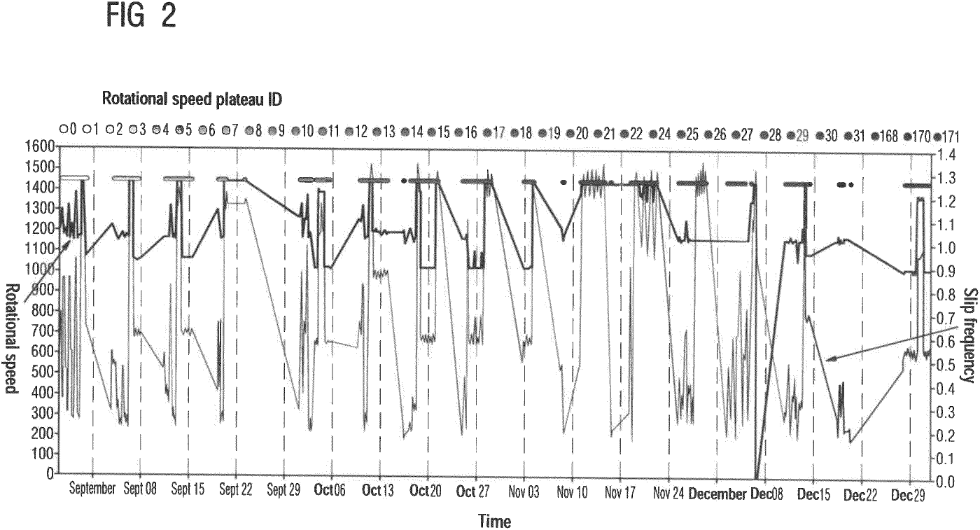

An example of a plateau detection is illustrated in FIG. 2. The time from September until the end of December - in other words, approx. four months - is plotted on the abscissa axis. The rotational speed and the slip frequency respectively are plotted on the ordinate axes.

FIG. 2 shows that several different operating plateaus have been detected. The plateaus are different when at least one of the at least two operating parameters - here rotational speed and slip frequency - differs from the other.

FIG. 2 also shows that different operating plateaus can be assigned different identification. In the present example, the plateaus are numbered consecutively and are applied with different colors - difficult to discern here, however, on account of the black-and-white representation.

In a step S3, a cluster analysis is carried out on the detected operating plateaus in order to detect operating point clusters. To this end, for example, a machine learning algorithm, for example, DBSCAN (Density-Based Spatial Clustering of Applications with Noise) can be used.

Different operating point clusters define different operating states of the electric rotary machine. In particular, the same threshold values for one (or more) vibration component(s) should apply to all points of an operating point cluster.

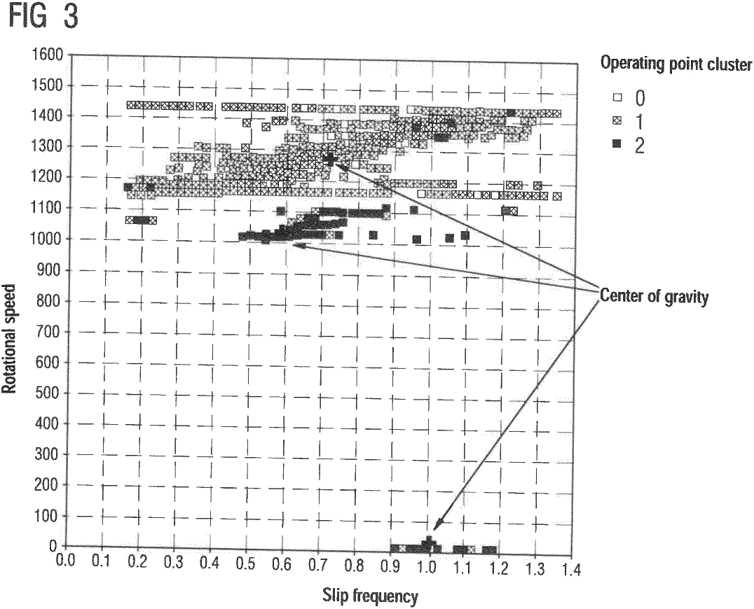

An example of a result of a cluster analysis is illustrated in FIG. 3. The slip frequency is plotted on the abscissa axis and a rotational speed is plotted on the ordinate axis. Three operating point clusters were detected. Different identification can be assigned to different operating point clusters (figure, number, etc.).

FIG. 3 shows that a center of gravity is determined for each operating point cluster. This can be done, for example, by calculating a cluster mean value.

In a step S4, a threshold value recommendation for the at least one spatial vibration component is determined for the defined operating states, preferably for each defined operating state. It goes without saying that there may be different recommendations for different operating states.

To determine recommendation(s), for example, a Bayesian Gaussian Mixture Model can be applied to the time series of the spatial vibration component.

The threshold value determined is preferably such that it is as close as possible, preferably within, for example, three standard deviations, to the expected value of the corresponding vibration amplitude and is intended to cap the RMS value (RMS for Root Mean Square) of the vibration measurement.

It may be expedient if a threshold value to be recommended is calculated for each operating state.

If the historical data comprises time series of two or three spatial vibration components, corresponding threshold value recommendations for the defined operating states can also be determined for further spatial vibration components.

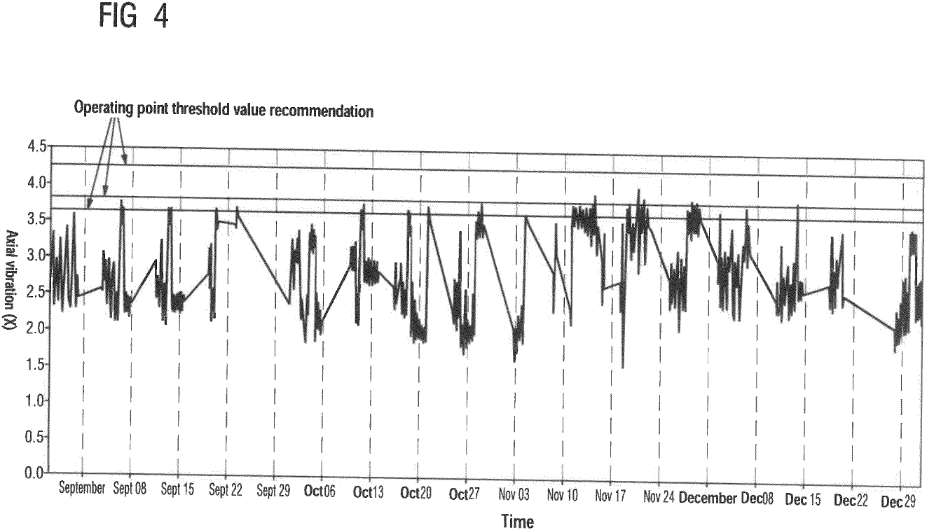

FIG. 4 illustrates three threshold value recommendations for the X-vibration component for three operating states which can be seen in FIG. 3. The time is plotted on the abscissa axis. The axial vibration (X) is plotted on the ordinate axis.

In a step S5, the defined operating states and the threshold values to be recommended for the defined operating states are provided. Thus, the model is trained and can be used.

FIG. 5 shows a diagrammatic view of a system 1 which is suitable for carrying out the training method described above. The system 1 comprises a machine readable storage medium 2 for storing, for example, buffering, machine-executable components and a processor unit 3, for example, one or more CPUs which can be operatively coupled to the storage medium 2 in order to execute the machine-executable components.

The storage medium 2 comprises machine-executable commands 4 which can be executed by the processor unit, and when they are executed, executes the learning method described above based on the historical data 5. The historical data can be made available to the storage medium 2 or stored thereon. The processor unit 3 can also be configured to download the historical data 5 from a database.

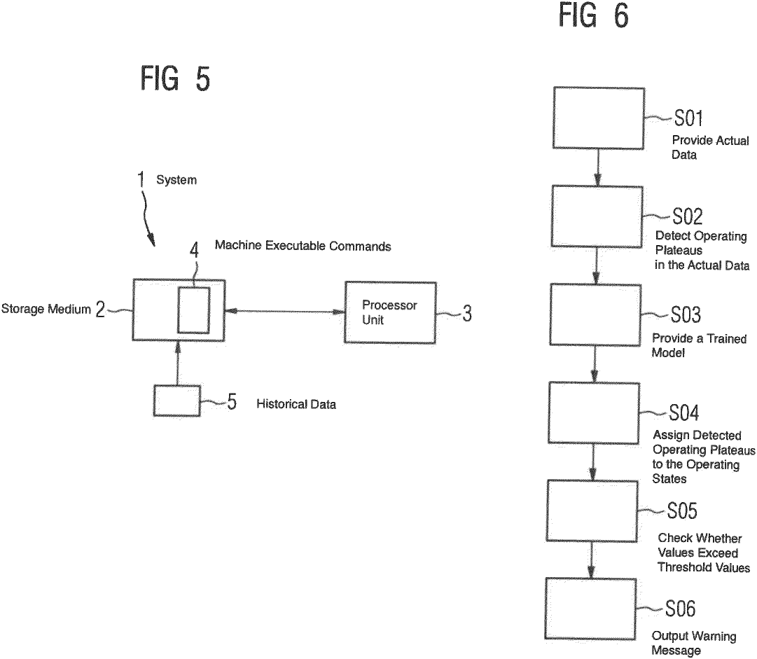

FIG. 6 shows a flow chart of a computer-implemented method corresponding to the method according to the invention for monitoring a status of an electric rotary machine.

In a step S01, actual data is provided, the actual data comprising time series of at least two operating parameters and of at least one spatial vibration component of the electric rotary machine.

As in the training method already discussed, the operating parameters are preferably the rotational speed and the slip frequency. The electric rotary machine can be an electric motor, in particular, a low-voltage motor.

Moreover, the actual data may comprise time series of two or three spatial components (X, Y and Z). The actual data may also contain time series of other high and/or low-frequency KPIs.

The time series of the actual data usually go back up to two days but not longer. They may also only include data recorded in the last 24 hours of the operating time of the machine.

In a step S02, operating plateaus are detected in the actual data, an operating plateau being defined in that the at least two operating parameters are/remain constant over a predeterminable period of time, for example, between 10 and 30 minutes, in particular 15 minutes. The detection of the operating plateaus in the actual data takes place in a manner similar to the detection of the operating plateaus in the historical data.

In a step S03, a trained model described as above is provided. The model can also be trained in situ, for example on the machine first, in order to apply it immediately to the real-time situation or to the ongoing operation of the machine.

In a step S04, the detected operating plateaus are assigned to the operating states defined by the trained model. Assignment is carried out for the purpose of mapping the time series or values of the at least one spatial vibration component corresponding to the detected operating plateaus to the operating states defined by the trained model.

In this case, each actual operating plateau can be assigned in each case to an operating state from the model. This can be achieved, for example, by calculating a Euclidean distance between the actual operating plateau and the center of gravity of the operating state from the model.

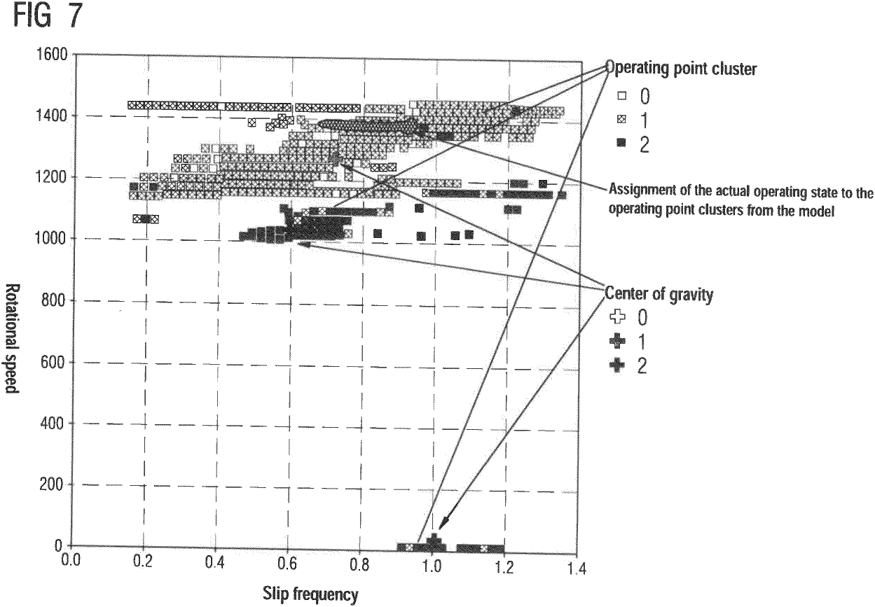

A result of such an assignment is shown by way of example in FIG. 7. FIG. 7 shows operating states which have been defined in the course of the cluster analysis of the historical data (cf. FIG. 3). These are marked with square dots. The operating plateaus from the actual data are to be seen as round (orange) dots. These can, for example, be assigned to the operating point cluster or operating state “0” on the basis of a smaller Euclidean distance from the corresponding center of gravity.

After the assignment, the proposed threshold value of the model, which was obtained for each operating state during the training, can now be used for the search for the threshold value exceedances.

In a step S05, it is therefore checked whether values (from the time series) of the at least one spatial vibration component exceed a threshold value recommended by the trained model.

In a step S06, a warning message is output according to a predeterminable criterion if the values of the at least one spatial vibration component exceed the threshold value.

In order to reduce the number of possible warning messages, a distinction can first be made between “oscillating” and “non-oscillating” (actual) operating plateaus. In this case, an operating plateau is referred to as non-oscillating if the value of the slip frequency within the operating plateau does not vary very greatly, for example its standard deviation is less than 0.5. Checking then takes place only in the non-oscillating operating plateaus.

Furthermore, a warning message can only be output if at least three successive values (three consecutive data points in the time series) of the at least one spatial vibration component exceed the threshold value. If a measurement is carried out every three minutes, this corresponds to a nine-minute exceedance of the threshold value.

As already discussed, the actual data can comprise time series of two or three spatial vibration components - X, Y, and Z components. It can be checked whether values of the two or three spatial vibration components exceed corresponding threshold values recommended by the trained model.

In this case, if one of the, for example, three spatial vibration components exceeds the threshold value, an effective value (RMS value) can be calculated in order to calculate a geometric mean from the calculated effective values. If the geometric mean exceeds a predetermined value, for example, 4 mm/s, the warning message is output. The value of 4 mm/s corresponds to a value for medium-sized machines from DIN ISO 10816-3.

The warning message can comprise a number of exceedances and associated time stamps.

If the electric rotary machine is operated for a lengthy period of time, for example for several months or years, it may be expedient to retrain or train the model. In this case, it can be provided that the actual data is stored and, at predetermined time intervals, for example every month, the model provided is retrained as described above on the basis of “new” historical data.

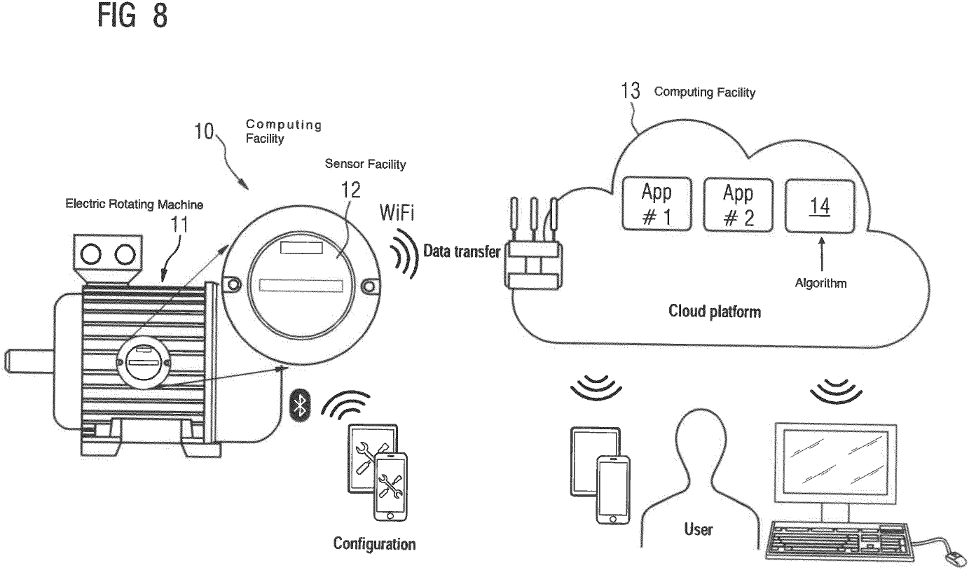

FIG. 8 shows a sensor and computing facility 10 for monitoring a status of an electric rotary machine 11. The machine is designed as an electric motor. The sensor and computing facility comprises a sensor facility 12 which is arranged on the electric motor 11. For example, the sensor facility 12 can be fastened to cooling ribs of the motor housing.

The electric motor 11 can be designed as a low-voltage motor.

During operation, the electric motor 11 is under a temporally variable load, the temporally variable load preferably being characterized by temporally varying torque or temporally varying rotational speed.

The sensor facility 12, which can be designed as a battery-operated smart box, is configured to detect data relating to the operation of the electric motor. In the example shown, the sensor facility 12 detects much of the data indirectly. For example, vibrations of the bearings cannot be received directly, but rather via the housing. This also relates to the temperature of the rotor, etc.

The acquired data may be in the form of time series. These comprise time series of at least two operating parameters (for example, rotational speed and slip frequency) and of at least one spatial vibration component of the electric motor.

The sensor facility 12 can be configured in situ, for example via a short-range radio connection, for example via a Bluetooth connection.

The sensor facility 12 has a data interface, for example Wi-Fi, which enables data transfer to a computing facility 13.

The computing facility 13 can be embodied, for example, as a cloud-based platform which provides various services App #1, App #2, etc. for monitoring and/or managing electric rotary machines, for example electric motors by users.

The sensor and computing facility 10, preferably the computing facility 13, includes commands which, when executed by the sensor and computing facility, cause the latter to carry out a training method described above and/or a status monitoring method described above.

The commands can be designed as part of an app.

In other words, the sensor and computing facility 10 is designed to detect drive data (motor data) and based on the drive data, to calculate vibration values and, based on the calculated vibration values, to carry out status monitoring of the electric drive based on threshold value checking. For this purpose, the sensor and computing facility 10 has an algorithm 14 which can be executed, trained and is capable of learning on the sensor and computing facility, wherein the algorithm 14, when it is executed on the sensor and computing facility:
determines at least two different operating states of the electric drive based on the drive data, and
based on the calculated vibration values, determines a vibration threshold value for each operating point
which carries out status monitoring of the electric drive based on threshold value checking, taking into account the determined vibration threshold values.

FIG. 8 shows an embodiment of the sensor and computing facility 10 which is embodied as a system comprising both shopfloor components, for example, the sensor facility 12 embodied as a smart box, and cloud components, for example, the computing facility 13.

However, the sensor and computing facility 10 can also be embodied as a unit which both comprises the sensor system in order to detect the data and provides the computing resources in order to execute the algorithm 14 and to process the data.

FIGS. 2 to 4, 7 and 8 make it clear that the sensor and computing facility 10 is configured to prepare or visualize calculated data (vibration values, torque, rotational speed) for visualization.

While the invention has been illustrated and described in connection with currently preferred embodiments shown and described in detail, it is not intended to be limited to the details shown since various modifications and structural changes may be made without departing in any way from the spirit and scope of the present invention. The embodiments were chosen and described in order to explain the principles of the invention and practical application to thereby enable a person skilled in the art to best utilize the invention and various embodiments with various modifications as are suited to the particular use contemplated.

What is claimed as new and desired to be protected by Letters Patent is set forth in the appended claims and includes equivalents of the elements recited therein:

What is claimed is:

1. A computer-implemented method for training a model for recommending threshold values of at least one spatial vibration component of an electric rotary machine, said method comprising:
providing historical data which comprise time series of at least two operating parameters and at least one spatial vibration component of the electric rotary machine;
detecting operating plateaus in the historical data, with each operating plateau being defined when the at least two operating parameters are constant over a predeterminable period of time;
performing a cluster analysis on the detected operating plateaus in order to detect operating point clusters, with the various operating point clusters defining various operating states of the electric rotary machine;
determining threshold values to be recommended for the defined operating states for the at least one spatial vibration component; and
providing the defined operating states and the threshold values to be recommended for the defined operating states.

2. The method of claim 1, further comprising estimating a center of gravity for each operating point cluster.

3. The method of claim 1, wherein the historical data comprise time series of two or three spatial vibration components, and further comprising determining threshold values to be recommended for the two or three spatial vibration components for the defined operating states.

4. The method of claim 1, wherein the operating parameters are rotational speed and slip frequency.

5. A computer-implemented method for monitoring a status of an electric rotary machine, said method comprising:
providing actual data which comprise time series of at least two operating parameters and at least one spatial vibration component of the electric rotary machine;
detecting operating plateaus in the actual data, with each operating plateau being defined when the at least two operating parameters are constant over a predeterminable period of time;
providing a model trained as set forth in claim 1;
assigning the detected operating plateaus to the operating states defined by the trained model in order to be able to map the time series of the at least one spatial vibration component to the operating states defined by the trained model;
checking whether values of the at least one spatial vibration component exceed a threshold value recommended by the trained model; and
when the values of the at least one spatial vibration component exceed the threshold value, outputting a warning message according to a predeterminable criterion.

6. The method of claim 5, wherein the warning message is output when at least three successive values of the at least one spatial vibration component exceed the threshold value.

7. The method of claim 5, wherein the actual data comprise time series of two or three spatial vibration components, and further comprising checking whether values of the two or three spatial vibration components exceed corresponding threshold values recommended by the trained model.

8. The method of claim 7, further comprising:
calculating for each value of the at least one spatial vibration component exceeding the threshold value an effective value for each spatial vibration component;
calculating a geometric mean from the calculated effective values; and outputting the warning message when the geometric mean exceeds a predetermined value.

9. The method of claim 8, wherein the warning message is output when the geometric mean exceeds 4 mm/s.

10. The method of claim 5, wherein the warning message comprises a number of exceedances and associated time stamps.

11. The method of claim 5, wherein the time series of the actual data go back up to two days.

12. The method of claim 5, further comprising:
storing the actual data; and
retraining the model provided at predetermined time intervals.

13. The method of claim 12, wherein the predetermined time intervals are every month.

14. A computer program product embodied on a non-transitory computer readable medium comprising commands which, when executed by a computer, cause the computer to carry out a method as set forth in claim 1.

15. A computer program product embodied on a non-transitory computer readable medium comprising commands which, when executed by a computer, cause the computer to carry out a method as set forth in claim 5.

16. A machine-readable storage medium comprising the computer program product of claim 14.

17. A machine-readable storage medium comprising the computer program product of claim 15.

18. A data transmission signal carrying commands which, when executed by a computer, cause the computer to carry out a method as set forth in claim 1.

19. A data transmission signal carrying commands which, when executed by a computer, cause the computer to carry out a method as set forth in claim 5.

20. A sensor and computing facility for monitoring a status of an electric rotary machine, said sensor and computing facility designed to detect data which relates to an operation of the electric rotary machine on the electric rotary machine and which comprises time series of at least two operating parameters and of at least one spatial vibration component of the electric rotary machine, said sensor and computing facility comprising commands, which, when executed by the sensor and computing facility, cause the sensor and computing facility to carry out a method as set forth in claim 1.

21. A sensor and computing facility for monitoring a status of an electric rotary machine, said sensor and computing facility designed to detect data which relates to an operation of the electric rotary machine on the electric rotary machine and which comprises time series of at least two operating parameters and of at least one spatial vibration component of the electric rotary machine, said sensor and computing facility comprising commands, which, when executed by the sensor and computing facility, cause the sensor and computing facility to carry out a method as set forth in claim 5.
